(19) United States
(12) Patent Application Publication
(10) Pub. No.: US 2010/0164060 A1
(43) Pub. Date: Jul. 1, 2010

(54) INDUCTOR FOR SEMICONDUCTOR DEVICE AND METHOD FOR FABRICATING THE SAME

(76) Inventor: Ji-Houn Jung, Jongno-gu (KR)

Correspondence Address: SHERR & VAUGHN, PLLC, 620 HERNDON PARKWAY, SUITE 320, HERNDON, VA, 20170, US

(21) Appl. No.: 12/643,694

(22) Filed: Dec. 21, 2009

(30) Foreign Application Priority Data
Dec. 30, 2008 (KR) 10-2008-0137401

(51) Int. Cl. H01L 29/86; H01L 21/02

(52) U.S. Cl. 257/531; 438/381; 257/E21.022; 257/E29.325

(57) ABSTRACT

An inductor for a semiconductor device and a method for fabricating the same includes a wafer, a first metal pad formed on the wafer and having a surface exposed from the surface of the wafer, a second metal pad formed on the wafer and having a surface exposed from the surface of the wafer, a first inductor line formed in the wafer and extending from the first metal pad and having a plurality of branches with a surface exposed from the surface of the wafer, and a second inductor line formed in the wafer and extending from the second metal pad and having a plurality of branches with a surface exposed from the surface of the wafer. The plurality of branches of the first inductor line and the plurality of branches of the second inductor line are arranged in parallel in an alternating pattern.

The present application claims priority under 35 U.S.C. §119 to Korean Patent Application No. 10-2008-0137401 (filed on Dec. 30, 2008), which are hereby incorporated by reference in its entirety.

### BACKGROUND

As multimedia services, which transmit audio and image data, is put into commercial service owing to development of mobile communication, band frequency has been expanded to require components to have clear definition of characteristics. Making components at a reduced size is also required following the development of the mobile communication. For the fabrication of components having such a reduction in size, a module in which an active device and a passive device are coupled, and a multi-chip in which the module is packaged together with an IC for the clear definition of characteristics of a modulized component are used.

Semiconductor devices such as in radio frequency (RF) devices may include a transistor, an inductor, a capacitor, a resistor, a varactor, and the like. In RF devices, an inductor is always used in an RF chip and occupies the largest area of the chip among unit devices. The inductor restricts RF characteristics due to parasitic capacitance caused by an inside structure and material and a resistance component. Therefore, in order to fabricate the chip to have a high device density packing density, it is important that the inductor has a minimum device area while the inductor maintains the same device capacity.

The planar spiral geometries may be used in fabrication of an inductor. Meaning, an uppermost metal of a substrate is bent in a two-dimensional plane. Typically, there are inductors of rectangular type, octagonal type, and circular type. Though inductance can more or less be enhanced depending on various geometric shapes of the inductors, all types of inductors have a problem in that the inductor occupies a large area in the RF chip.

### SUMMARY

Embodiments relate to an inductor for a semiconductor device and a method for fabricating the same.

Embodiments relate to an inductor for a semiconductor device and a method for fabricating the same which reduces the area the inductor occupies in an RF chip.

In accordance with embodiments, an inductor for a semiconductor device can include at least one of the following: first and second metal pads having surfaces exposed from an wafer, a first inductor line extended from the first metal pad in a shape of a fork having a plurality of branches, the first inductor line having a surface exposed from the surface of the wafer, and a second inductor line extended from the second metal pad in a shape of a fork having a plurality of branches, having a surface exposed from the surface of the wafer. The plurality of branches of the first inductor line and the plurality of branches of the second inductor line are arranged in parallel in an alternating pattern.

In accordance with embodiments, the first and second inductor lines are formed by placing polysilicon in the wafer. The first and second inductor lines can have a depth A in the wafer greater than a line width B of the first and second inductor lines.

In accordance with embodiments, a method for fabricating an inductor for a semiconductor device can include at least one of the following: forming a photoresist pattern on and/or over a wafer, forming fork-shaped two deep trenches each having plurality of branches arranged in parallel in an alternating pattern by etching the wafer using the photoresist pattern as an etch mask, forming first and second inductor lines by depositing polysilicon in the trenches, and then forming a first metal pad connected to the first inductor line and a second metal pad connected to the second inductor line at the wafer.

In accordance with embodiments, forming the fork-shaped two deep trenches includes forming a depth of the trench greater than a width of the trench. Forming the first and second inductor lines includes depositing the polysilicon on and/or over the wafer including filling the trenches and then etching back the polysilicon to planarize the surface of the wafer.

In accordance with embodiments, a method for fabricating an inductor for a semiconductor device can include at least one of the following: forming a photoresist pattern on and/or over a wafer, forming a deep trench in the wafer using the photoresist pattern as an etch mask, depositing polysilicon in the trench to form an inductor line, and then forming a metal pad on and/or over the wafer connected to the inductor line.

In accordance with embodiments, an inductor for a semiconductor device can include at least one of the following: a wafer; a first metal pad formed over the wafer and having a surface exposed from the surface of the wafer; a second metal pad formed over the wafer and having a surface exposed from the surface of the wafer; a first inductor line formed in the wafer and extending from the first metal pad and having a plurality of branches with a surface exposed from the surface of the wafer; and a second inductor line formed in the wafer and extending from the second metal pad and having a plurality of branches with a surface exposed from the surface of the wafer such that the plurality of branches of the first inductor line and the plurality of branches of the second inductor line are arranged in parallel in an alternating pattern.

In accordance with embodiments, an inductor for a semiconductor device can include at least one of the following: a wafer; a first metal pad formed on the wafer and having a surface exposed from the surface of the wafer; a second metal pad formed on the wafer and having a surface exposed from the surface of the wafer; a first inductor line formed in the wafer, the first inductor line comprising a first branch extending from the first metal pad in a first direction relative thereto, a second branch extending in a direction perpendicular to the first branch, and third and fourth branches extending from terminating ends of the second branch in a direction parallel to the first branch; and a second inductor line formed in the wafer, the second inductor line comprising a fifth branch extending from the second metal pad in a second direction relative thereto, a sixth branch extending in a direction perpendicular to the fifth branch, and seventh and eight branches extending from terminating ends of the sixth branch in a direction parallel to the fifth branch.

In accordance with embodiments, a method for fabricating an inductor for a semiconductor device can include at least one of the following: forming a photoresist pattern over a wafer; simultaneously forming a first plurality and a second plurality of trenches each having plurality of branches arranged in parallel in an alternating pattern by etching the wafer using the photoresist pattern as an etch mask; simultaneously forming first and second inductor lines by depositing polysilicon in the trenches; and then forming a first metal pad at the wafer connected to the first inductor line and a second metal pad at the wafer connected to the second inductor line.

### DRAWINGS

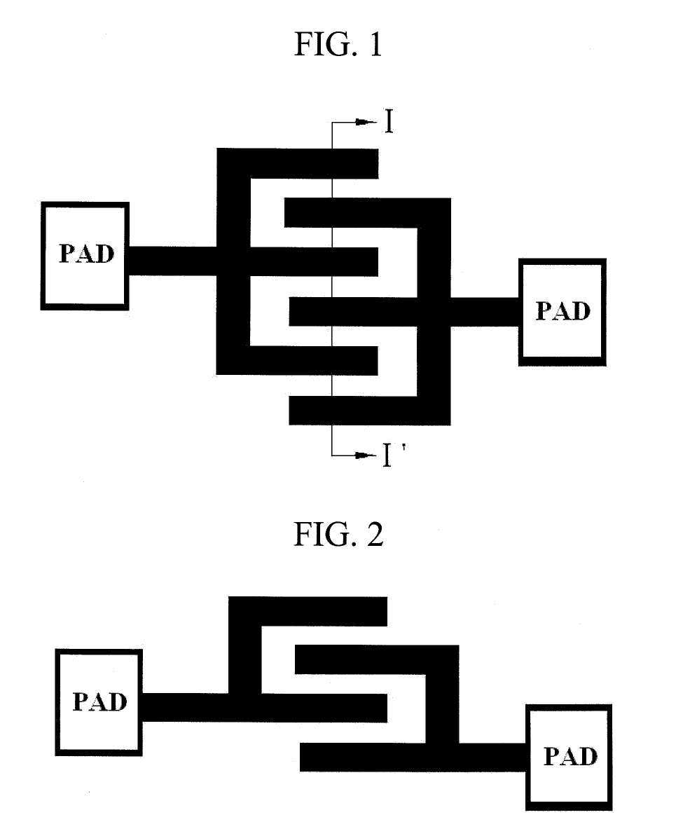

Example FIGS. 1 to 4 illustrate fork-shaped inductors and a method for fabricating an inductor for a semiconductor device in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts.

In accordance with embodiments, forming an inductor by placing conductive polysilicon in a trench instead of a metal after forming a deep trench in a wafer, and forming a metal pad at the wafer connected to the inductor line, an inductor is fabricated at a RF chip by trench etching and deposition of polysilicon.

As illustrated in example FIGS. 1 to 3, the inductor in accordance with embodiments has a plurality of inductor lines which combine to form a fork-shape having a plurality of branches, in which the branches of different inductor lines are arranged parallel to one another in alternating pattern.

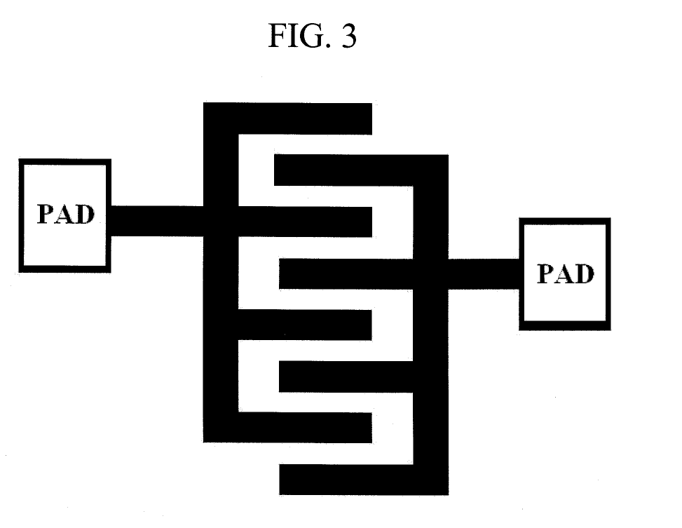

Example FIG. 1 illustrates a plan view of fork-shaped inductors having three branches. Example FIG. 2 illustrates a plan view of fork-shaped inductors having two branches. Example FIG. 3 illustrates a plan view of fork-shaped inductors having four branches. The overall number of the branches can be determined taking inductance into account.

As illustrated in example FIGS. 1 to 3, the inductor for a semiconductor device in accordance with embodiments includes first and second metal pads PAD, and first and second inductor lines each extending from a respective one of the first and second metal pads to have a plurality of branches arranged in parallel to one another in an alternating pattern. The metal pads are formed in the wafer such that surfaces of the metal pads are exposed.

As illustrated in example FIG. 1, the first inductor line is also formed in the wafer, and a surface thereof is exposed. The first inductor line is formed to extend from the first metal pad by way of a first branch extending in a first direction relative to the first metal pad. A second branch extends in a perpendicular direction relative to and also bisects the first branch. Third and fourth branches extend at terminating ends of the second branch in a parallel direction relative to the first branch. Accordingly, the plurality of branches combine to form a fork-shaped first inductor line.

The second inductor line is also formed in the wafer, and a surface thereof is exposed. The second inductor line is formed to extend from the second metal pad by way of a first branch extending in a first direction relative to the second metal pad and opposite to the direction of the first branch of the first inductor line. A second branch extends in a perpendicular direction relative to and also bisects the first branch. Third and fourth branches extend at terminating ends of the second branch in a parallel direction relative to the first branch. Accordingly, the plurality of branches combine to form a fork-shaped second inductor line.

As illustrated in example FIG. 2, the first inductor line is also formed in the wafer, and a surface thereof is exposed. The first inductor line is formed to extend from the first metal pad by way of a first branch extending in a first direction relative to the first metal pad. A second branch extends in a perpendicular direction relative to the first branch. A third branch extends at a terminating end of the second branch in a parallel direction relative to the first branch. Accordingly, the plurality of branches combine to form a fork-shaped first inductor line.

The second inductor line is also formed in the wafer, and a surface thereof is exposed. The second inductor line is formed to extend from the second metal pad by way of a first branch extending in a first direction relative to the first metal pad and opposite to the direction of the first branch of the first inductor line. A second branch extends in a perpendicular direction relative to the first branch. A third branch extends at a terminating end of the second branch in a parallel direction relative to the first branch. Accordingly, the plurality of branches combine to form a fork-shaped second inductor line.

As illustrated in example FIG. 3, the first inductor line is also formed in the wafer, and a surface thereof is exposed. The first inductor line is formed to extend from the first metal pad by way of a first branch extending in a first direction relative to the first metal pad. A second branch extends in a perpendicular direction relative to and also bisects the first branch. Third and fourth branches extend at terminating ends of the second branch in a parallel direction relative to the first branch. A fifth branch extends from the second branch and between the third and fourth branches in a parallel direction relative to the first, second and third branches. Accordingly, the plurality of branches combine to form a fork-shaped first inductor line.

The second inductor line is also formed in the wafer, and a surface thereof is exposed. The second inductor line is formed to extend from the second metal pad by way of a first branch extending in a first direction relative to the first metal pad. A second branch extends in a perpendicular direction relative to and also bisects the first branch. Third and fourth branches extend at terminating ends of the second branch in a parallel direction relative to the first branch. A fifth branch extends from the second branch and between the third and fourth branches in a parallel direction relative to the first, second and third branches. Accordingly, the plurality of branches combine to form a fork-shaped second inductor line.

In accordance with embodiments illustrated in example FIGS. 1 to 3, in order to form the first to second inductor lines in the wafer with surfaces thereof exposed, polysilicon can be deposited in trenches formed in the wafer and then planarized. Although a ratio of width to depth of the trench can vary depending on a design rule, in accordance with embodiments, the ratio of depth to width of the trench is greater. Accordingly, if the depth of at least one of the first and second inductor lines in the wafer is A, and a line width of the first or second inductor line is B, A can be greater than B.

As illustrated in FIGS. 1 to 3 again, the plurality of branches of the first and second inductor lines are not connected to each other, but arranged in parallel to one another in an alternating pattern.

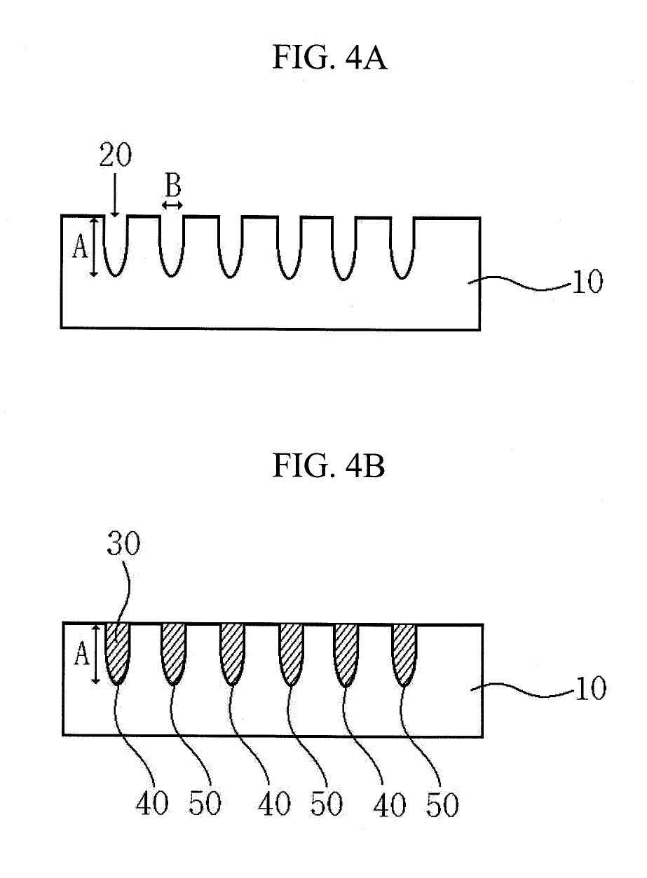

Example FIGS. 4A and 4B illustrate a method for fabricating an inductor for a semiconductor device in accordance with embodiments, focused on a section across I-I′ of the inductors in example FIG. 1.

As illustrated in FIG. 4A, a plurality of deep trenches 20 are formed in wafer 10. In order to form trenches 20, a photoresist pattern is formed on and/or over wafer 10 for forming the first to second inductor lines having the plurality of branches arranged in parallel to one another in an alternating manner. Wafer 10 is then etched using the photoresist mask pattern as an etch mask to form trench 20 having the plurality of branches of the two forks arranged in parallel to one another in an alternating manner. If it is assumed that depth A of trench 20 and a line width B of trench 20 is formed such that A is greater than B. Meaning, a ratio of A to B is made greater.

As illustrated in FIG. 4B, trenches 20 are filled with polysilicon 30 to form first inductor line 40 and second inductor line 50 having the plurality of branches arranged in parallel to one another in an alternating manner. Then, the deposited polysilicon is etched back to planarize the surface of wafer 10, thereby forming first inductor lines 40 and second inductor lines 50 having a surface thereof exposed in wafer 10. A first metal pad connected to first inductor line 40 and a second metal pad connected to second inductor line 50 are formed. The metal pads are also formed in wafer 10 and have surfaces thereof exposed.

In accordance with embodiments, instead of the deposition of polysilicon, the inductor lines 40, 50 can be formed by ion injection. For example, a photoresist pattern is formed on and/or over wafer 10, and then conductive ion material is injected into wafer 10 using the photoresist pattern as a mask to form the inductor lines 40, 50.

In accordance with embodiments, an inductor in a RF chip, particularly, in a surface of the wafer, by trench etching and the deposition of polysilicon, an occupying area of the inductor in the chip can be minimized, and competitiveness can be secured, which meets a trend of providing the RF chip to have multi-purpose and fabricated of thin films.

Though the inductor may be attached to the chip after the inductor is formed, in accordance with embodiments, the inductor is formed in the chip itself directly to embody the system-on-chip (SOC), permitting all of passive devices to be formed on one chip. In accordance with embodiments, fabrication of the chip of a high device packing density, multi-purpose, and thin film may be formed.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An apparatus comprising:
a wafer;
a first metal pad formed on the wafer and having a surface exposed from the surface of the wafer;
a second metal pad formed on the wafer and having a surface exposed from the surface of the wafer;
a first inductor line formed in the wafer and extending from the first metal pad and having a plurality of branches with a surface exposed from the surface of the wafer; and
a second inductor line formed in the wafer and extending from the second metal pad and having a plurality of branches with a surface exposed from the surface of the wafer,
wherein the plurality of branches of the first inductor line and the plurality of branches of the second inductor line are arranged in parallel in an alternating pattern.

2. The apparatus of claim 1, wherein the apparatus comprises an inductor for a semiconductor device.

3. The apparatus of claim 1, wherein the first and second inductor lines comprise polysilicon.

4. The apparatus of claim 1, wherein the first and second inductor lines comprise a conductive ion material.

5. The apparatus of claim 1, wherein the first inductor line has a depth in the wafer greater than a width thereof.

6. The apparatus of claim 1, wherein the second inductor line has a depth in the wafer greater than a width thereof.

7. The apparatus of claim 1, wherein the first and second inductor lines each have a depth in the wafer greater than a width thereof.

8. An apparatus comprising:
a wafer;
a first metal pad formed on the wafer and having a surface exposed from the surface of the wafer;
a second metal pad formed on the wafer and having a surface exposed from the surface of the wafer;
a first inductor line formed in the wafer, the first inductor line comprising a first branch extending from the first metal pad in a first direction relative thereto, a second branch extending in a direction perpendicular to the first branch, and third and fourth branches extending from terminating ends of the second branch in a direction parallel to the first branch; and
a second inductor line formed in the wafer, the second inductor line comprising a fifth branch extending from the second metal pad in a second direction relative thereto, a sixth branch extending in a direction perpendicular to the fifth branch, and seventh and eight branches extending from terminating ends of the sixth branch in a direction parallel to the fifth branch.

9. The apparatus of claim 8, wherein the apparatus comprises an inductor for a semiconductor device.

10. The apparatus of claim 8, wherein the branches of the first inductor line and the branches of the second inductor line are arranged in parallel in an alternating pattern.

11. The apparatus of claim 8, wherein the first and second inductor lines comprise polysilicon.

12. The apparatus of claim 8, wherein the first and second inductor lines comprise a conductive ion material.

13. The apparatus of claim 8, wherein the first inductor line has a depth in the wafer greater than a width thereof.

14. The apparatus of claim 8, wherein the second inductor line has a depth in the wafer greater than a width thereof.

15. The apparatus of claim 8, wherein the first and second inductor lines each have a depth in the wafer greater than a width thereof.

16. A method comprising:
forming a photoresist pattern over a wafer;
simultaneously forming a first plurality and a second plurality of trenches each having plurality of branches arranged in parallel in an alternating pattern by etching the wafer using the photoresist pattern as an etch mask;
simultaneously forming first and second inductor lines by forming polysilicon in the trenches; and then
forming a first metal pad at the wafer connected to the first inductor line and a second metal pad at the wafer connected to the second inductor line.

17. The method of claim 16, wherein simultaneously forming the first plurality and the second plurality of trenches comprises forming the first plurality and second plurality of trenches at a depth greater than a width thereof.

18. The method of claim 16, wherein simultaneously forming first and second inductor lines comprises:
depositing the polysilicon over the wafer including filling the trenches; and then
etching back the polysilicon.

19. The method of claim 16, wherein simultaneously forming the first plurality and the second plurality of trenches comprises etching the wafer such that the branches of the first inductor line and the branches of the second inductor line are arranged in parallel in an alternating pattern.

20. The method of claim 16, wherein:
the first inductor line comprises a first branch extending from the first metal pad in a first direction relative thereto, a second branch extending in a direction perpendicular to the first branch, and third and fourth branches extending from terminating ends of the second branch in a direction parallel to the first branch; and
the second inductor line comprises a fifth branch extending from the second metal pad in a second direction relative thereto, a sixth branch extending in a direction perpendicular to the fifth branch, and seventh and eight branches extending from terminating ends of the sixth branch in a direction parallel to the fifth branch.
